(19) United States
(12) Patent Application Publication
(10) Pub. No.: US 2016/0078961 A1
(43) Pub. Date: Mar. 17, 2016

(54) METHOD OF ERASING A NONVOLATILE MEMORY FOR PREVENTING OVER-SOFT-PROGRAM

(71) Applicant: ELITE SEMICONDUCTOR MEMORY TECHNOLOGY INC., Hsinchu (TW)

(72) Inventor: CHIH-HAO CHEN, NEW TAIPEI CITY (TW)

(21) Appl. No.: 14/485,691

(22) Filed: Sep. 13, 2014

(51) Int. Cl. G11C 16/34; G11C 16/14

(52) U.S. Cl. CPC G11C 16/3459; G11C 16/14

(57) ABSTRACT

A method of erasing a nonvolatile memory for preventing over-soft-program comprises performing an erase operation on at least one cell among a plurality of cells in the nonvolatile memory; applying a first soft program verify operation; applying a second soft program verify operation, wherein the second verify voltage is lower than the first verify voltage; determining whether the threshold voltage of the cell is lower than the first verify voltage or the second verify voltage; performing a soft program operation with a first soft program voltage when the threshold voltage of the cell is lower than the first verify voltage and higher than the second verify voltage; and performing the soft program operation with a second soft program voltage higher than the first soft program voltage when the threshold voltage of the cell is lower than both of the first verify voltage and the second verify voltage.

### BACKGROUND OF THE INVENTION

1. Field of the Invention

The instant disclosure relates to a nonvolatile memory; in particular, to a method of erasing a nonvolatile memory.

2. Description of Related Art

A non-volatile memory (NVM), such as a flash memory, commonly has program and erase cycles that to be effective need to be uninterrupted. On occasion, however, an interruption does occur. This is typically most likely to occur during an erase operation because erase operations are typically quite long because erase operations commonly include many steps such as pre-erase program, erase, and soft programming. This interruption is normally a result of a loss or reduction in power and thus called a brownout. The brownouts can occur at any point in the erase operation and information as to precisely what state that is may be impossible or at least difficult to store. Also, the cells have a distribution so the precise state of the cells is similarly difficult to know even if the precise point in the erase operation where the brownout has occurred is precisely known. As shown in FIG. 1A, the distribution of the threshold voltages (Vt) of the cells could be indicated by the region of all “1” and the region of all “0”, in which the region of all “1” means the threshold voltage distribution of the cells when the state of each cell is “1” in binary, the region of all “0” means the threshold voltage distribution of the cells when the state of each cell is “0” in binary. And the brownout recovery generally is simply to repeat the erase operation from the beginning Nonetheless, there are brownouts that result in a subsequent failure to erase, especially when some cells are left in the over-erased state (with the threshold voltage lower than zero volt) as a result of the brownout. For example, referring to FIG. 1A, the cells in the over-erased region (covered by the left boundary of the all “1” region and the dash line in the left of the all “1” region) are over-erased. And, the cell CE1 at the left edge of the all “1” region may be over-programmed to exceed the right edge of the prior all “1” region (that is the cell CE1 is changed to the cell CE1′) due to surplus program voltage, thus erroneous reading of the cell may occurred. And, on the other hand, the cell CE2 at the left edge of the over erase region has to be programmed to be the cell CE2′ having threshold voltage larger than zero volt. However, the threshold voltage larger than zero voltage is not high enough to suppress the channel leakage for nanometer technology. More soft-program shots are required to program the cell threshold voltage larger than 0.7V. That will increase soft-program time especially for the slow soft-program cell. Accordingly, it is desirable to provide a technique that provides a reduction in failures due to brownout without sacrificing too much soft-program time.

### SUMMARY OF THE INVENTION

The object of the instant disclosure is to provide a method of erasing a nonvolatile memory. The method or so called algorithm is for preventing over-soft-program to the nonvolatile memory cells.

In order to achieve the aforementioned objects, according to an embodiment of the instant disclosure, a method of erasing a nonvolatile memory for preventing over-soft-program is offered. The method comprises performing an erase operation on at least one cell among a plurality of cells in the nonvolatile memory; applying a first soft program verify operation to determine whether a threshold voltage of the cell is lower than a first verify voltage; applying a second soft program verify operation to determine whether the threshold voltage of the cell is lower than a second verify voltage, wherein the second verify voltage is lower than the first verify voltage; determining whether the threshold voltage of the cell is lower than the first verify voltage and determining whether the threshold voltage of the cell is lower than the second verify voltage; performing a soft program operation with a first soft program voltage when the threshold voltage of the cell is lower than the first verify voltage and higher than the second verify voltage; and performing the soft program operation with a second soft program voltage higher than the first soft program voltage when the threshold voltage of the cell is lower than both of the first verify voltage and the second verify voltage.

In summary, the method of erasing a nonvolatile memory for preventing over-soft-program applies two soft program verify operations to determine the soft program voltage, that is the memory cell with higher threshold voltage is soft-programmed with a lower soft program voltage in order to preventing over-soft-program. The memory cell with lower threshold voltage is soft-programmed with a higher soft program voltage in order to speed up over-soft-program speed and thus save soft program time.

In order to further the understanding regarding the instant disclosure, the following embodiments are provided along with illustrations to facilitate the disclosure of the instant disclosure.

### BRIEF DESCRIPTION OF THE DRAWINGS

FIG. 1A shows a threshold voltage distribution of the conventional nonvolatile memory cells with an over programmed cell;

FIG. 1B shows a threshold voltage distribution of the conventional nonvolatile memory cells with a cell programmed with a slow soft-program cell;

FIG. 2 shows a flow chart of a method of erasing a nonvolatile memory for preventing over-soft-program according to an embodiment of the instant disclosure;

FIG. 3A shows a shift of the threshold voltage of a nonvolatile memory cells due to the soft program operation with a first soft program voltage according to an embodiment of the instant disclosure;

FIG. 3B shows a shift of the threshold voltage of a nonvolatile memory cells due to the soft program operation with a second soft program voltage according to an embodiment of the instant disclosure; and

FIG. 4 shows the soft program (SPGM) characteristics of the nonvolatile memory cells.

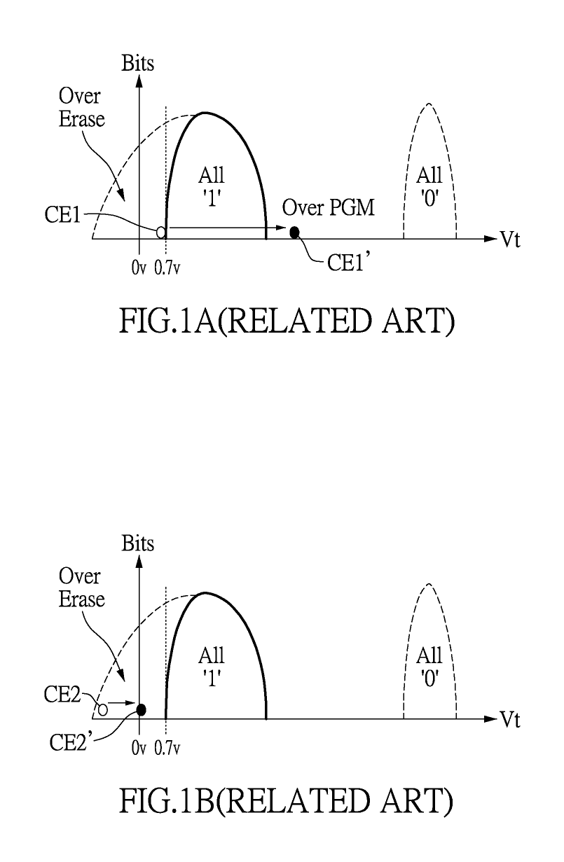

### DETAILED DESCRIPTION OF THE PREFERRED EMBODIMENTS

The aforementioned illustrations and following detailed descriptions are exemplary for the purpose of further explaining the scope of the instant disclosure. Other objectives and advantages related to the instant disclosure will be illustrated in the subsequent descriptions and appended drawings.

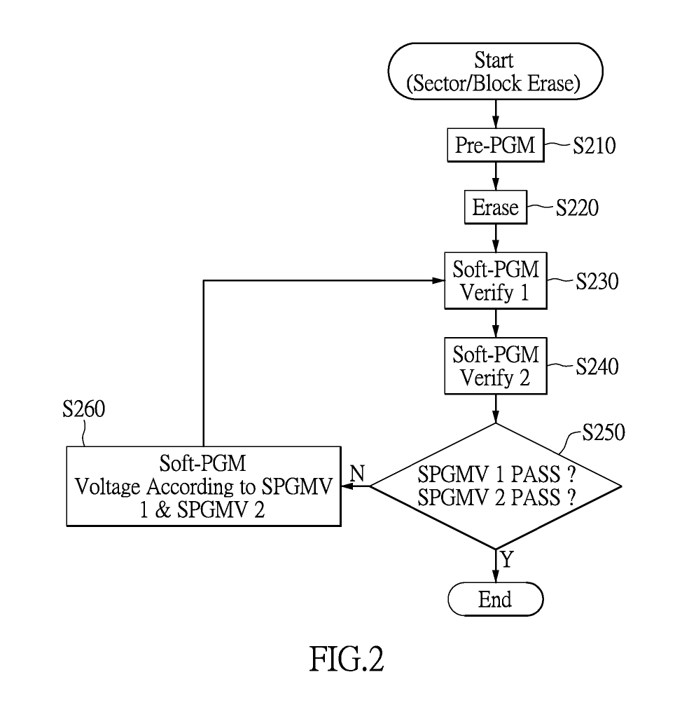

Please refer to FIG. 2 showing a flow chart of a method of erasing a nonvolatile memory for preventing over-soft-program according to an embodiment of the instant disclosure. The nonvolatile memory may be a flash memory for example, but the instant disclosure is not so restricted. The method comprises following steps. Firstly, in step 210, performing a pre-program operation. In general, to facilitate a tight erase threshold voltage (Vt) distribution, all the memory cells are firstly pre-programmed before commencing an erase operation. This pre-program operation is performed to ensure that all the cells are at a uniformly high threshold voltage (Vt) before they are then globally erased. This pre-program operation can be thought of as a pre-conditioning of the array prior to erase operation. In most of the prior art, the most preferred method for pre-programming, and thus for programming, is the use of Channel Hot Electron Injection, or CHEI. When the memory cell is a flash memory cell, the typical flash memory cell uses a floating gate to store a bit by the presence or absence of a charge. In general, pre-programming or programming is a process of injecting hot electrons into floating gate.

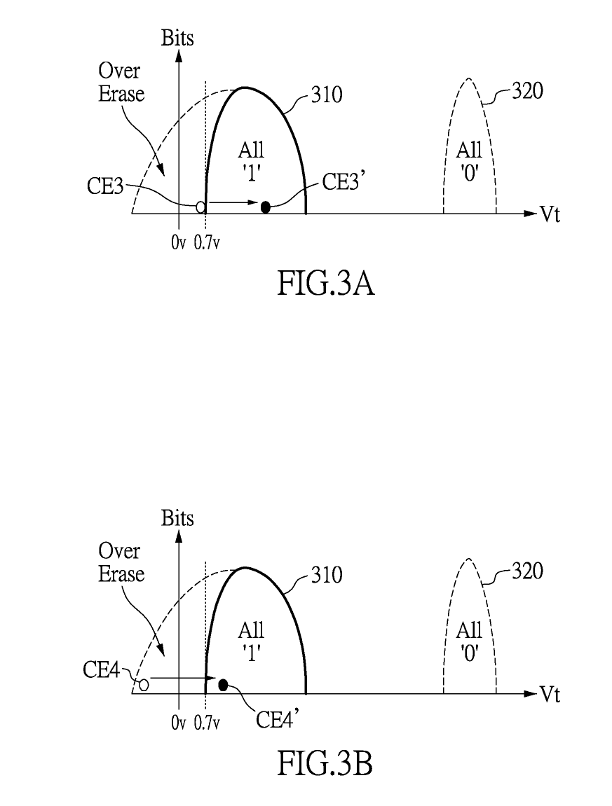

Then, in step S220, performing an erase operation on at least one cell among a plurality of cells in the nonvolatile memory. In the nonvolatile memory array, each memory cell in the array is connected to a bit-line (BL) and a word-line (WL). In general, the erase operation is performed by applying an erase voltage to the word-line of at least one cell of the nonvolatile memory, and the erase voltage is a negative voltage. Specifically, each memory cell in one column of the array is connected to the corresponding bit-line. Bit-lines are conductive stripes perpendicular to the word-lines and are physically connected to the source/drains of the cell-transistors (for example, MOS-transistors). The bit-lines are the lines through which information is written/read to/from the memory cells. The control gates of the memory cells in the same row are connected to the corresponding word-line. When the memory cell is a flash memory cell, the erase operation is a process of pulling electrons out of the floating gate. The erase operation may be performed by floating one of a source select line and a drain select line or applying a bias voltage to one of the source select line and the drain select line or applying a drain-source bias, then applying a ground voltage (for example, OV) to a word-line included, and then applying a high voltage to a well formed in a semiconductor substrate. Referring to FIG. 3A, a first threshold voltage distribution (curve 310) is obtained when the plurality of cells are stored as “1” and a second threshold voltage distribution (curve 320) with voltages higher than the voltages of first threshold voltage distribution is obtained when the plurality of cells are stored as “0”. The threshold voltages (Vt) of the cells to be erased through the above erase operation are distributed in an erased state with the threshold voltage distribution curve 310 as illustrated in FIG. 3A. After the erase operation, some cells may have been over erased, producing an excessively low threshold voltage (Vt), the threshold voltage (Vt) of the over erased cells is located in the over erased region covered by the left boundary of threshold voltage distribution curve 310 and the dash line in the left of the threshold voltage distribution curve 310. Briefly, the erase operation performed at least some cells of the plurality of cells, and at least some of the plurality of cells may be over-erased. These over erased cells have to be soft programmed in the steps thereafter, in order to correct the threshold voltage distribution of the excessively-erased cells.

Then, in step S230, applying a first soft program verify operation to determine whether a threshold voltage (Vt) of the cell is lower than a first verify voltage. For example, the first verify voltage may be the voltage of 0.7V indicated in FIG. 3A and FIG. 3B, but it is not intended to limit the scope of the instant disclosure. If the threshold voltage (Vt) of the cell is higher than the first verify voltage (for example, 0.7V), the threshold voltage (Vt) of the cell is located between the left edge and the right edge of the threshold voltage distribution curve 310, it means the cell is not needed to be soft programmed. If the threshold voltage (Vt) of the cell is lower than the first verify voltage, it means the cell is needed to be soft programmed. The predetermined first verify voltage is the same as to the minimum threshold voltage of the not over erased cell (or the maximum threshold voltage of the over erased cell).

Then, in step S240, applying a second soft program verify operation to determine whether the threshold voltage (Vt) of the cell is lower than a second verify voltage, wherein the second verify voltage is lower than the first verify voltage. The second verify voltage could be also predetermined. Both of the first verify voltage and the second verify voltage may depend on process parameters of the nonvolatile memory. When the first verify voltage is 0.7V the second verify voltage is a voltage lower than 0.7V, for example the second verify voltage may be −2V. The step S240 is to identify whether the threshold voltage (Vt) of the over erased cell is located in the more negative region or the more positive region of the over erased region (covered by the left boundary of threshold voltage distribution curve 310 and the dash line in the left of the threshold voltage distribution curve 310). In exemplary, the over erased cell CE3 is located in the more positive region of the over erased region, that is the threshold voltage (Vt) of the cell CE3 is closed to the first verify voltage (0.7V). The over erased cell CE4 is located in the more negative region of the over erased region, that is the threshold voltage (Vt) of the cell CE4 is quite far from the first verify voltage (0.7V). In order to reduce the outcome of over erase, these two over erased cells need to be respectively soft programmed with different soft program voltages which would be described in step S260.

After the step S230 and the step S240 is carried out, then go to step S250, determining whether the threshold voltage (Vt) of the cell is lower than the first verify voltage and determining whether the threshold voltage (Vt) of the cell is lower than the second verify voltage. The first soft program verify operation (SPGMV 1) is determined to be failed when the threshold voltage (Vt) of the cell is lower than the first verify voltage, the first soft program verify operation (SPGMV 1) is determined to be passed when the threshold voltage (Vt) of the cell is higher than or equal to the first verify voltage. The second soft program verify operation (SPGMV 2) is determined to be failed when the threshold voltage (Vt) of the cell is lower than the second verify voltage, the second soft program verify operation (SPGMV 2) is determined to be passed when the threshold voltage (Vt) of the cell is higher than or equal to the second verify voltage. For example, when the first verify voltage is 0.7V and the second verify voltage is −2V, the cell with threshold voltage (Vt) higher than 0.7V would pass the first soft program verify operation (SPGMV1) and the second soft program verify operation (SPGMV 2), which mean the cell with threshold voltage (Vt) higher than 0.7V would not be soft programmed. If the threshold voltage (Vt) of the cell is lower than 0.7V but higher than −2V or lower both of 0.7V and −2V, the cell would be soft programmed to eliminate the outcome of over erase. In other words, the soft program operation (step S260) would not be carried out when both of the first soft program verify operation and the second soft program verify operation are passed. And, the soft program operation (step S260) would be carried out when any of the first soft program verify operation and the second soft program verify operation are failed.

In step S260, performing a soft program operation with a first soft program voltage when the threshold voltage (Vt) of the cell is lower than the first verify voltage and higher than the second verify voltage and performing the soft program operation with a second soft program voltage higher than the first soft program voltage when the threshold voltage (Vt) of the cell is lower than both of the first verify voltage and the second verify voltage. For example, referring to FIG. 3A, the threshold voltage (Vt) of the over erased cell CE3 is lower than the first verify voltage (0.7V) and higher than the second verify voltage (−2V), the cell CE3 is soft programmed with a first soft program voltage in order to make the threshold voltage (Vt) be between maximum voltage and the minimum voltage of the threshold voltage distribution curve 310, and the cell CE3 is changed to the cell CE3′ as shown in FIG. 3A. That is, a threshold voltage distribution (curve 310) is obtained when the plurality of cells are stored as “1” after the erase operation is performed, then the soft program operation with the first soft program voltage is performed to change the threshold voltage of the over-erased cells to be in the region of the threshold voltage distribution (curve 310) when the first soft program verify operation (SPGMV 1) is failed and the second program verify operation (SPGMV 2) is passed. For another example, when the threshold voltage (Vt) of the over erased cell CE4 is lower than the first verify voltage (0.7V) and the second verify voltage (−2V), the cell CE4 is soft programmed with a second soft program voltage in order to make the threshold voltage (Vt) be between maximum voltage and the minimum voltage of the threshold voltage distribution curve 310, and the cell CE4 is changed to the cell CE4′ as shown in FIG. 3B. That is, a threshold voltage distribution (curve 310) is obtained when the plurality of cells are stored as “1” after the erase operation is performed, then the soft program operation with the second soft program voltage is performed to change the threshold voltage of the over-erased cells to be in the region of the threshold voltage distribution (curve 310) when the first soft program verify operation (SPGMV 1) and the second program verify operation (SPGMV 2) are failed. In short, the over erased cells with threshold voltages lower than 0.7V but higher than −2V would be soft programmed with a lower program voltage, and the other over erased cells with threshold voltages (Vt) lower than 0.7V but higher than −2V would be soft programmed with a higher program voltage. The aforementioned first soft program voltage and the second soft program voltage higher than the first soft program voltage depending on process parameters of the nonvolatile memory, and the first soft program voltage and the second soft program voltage can be adjusted according to the threshold voltage distribution. In one embodiment, the first soft program voltage and the second soft program voltage could be positive voltages applied to the word-lines and the bit-lines of the memory cells.

Then, the steps of applying the first soft program verify operation (S230) and the second soft program verify operation (S240) are repeated after the soft program operation (S260) is performed, and then determining whether the threshold voltage (Vt) of the cell is higher than the first verify voltage or the second verify voltage (S250) again. Then, when any of the first soft program verify operation and the second soft program verify operation are failed, the soft program operation (step S260) would be carried out again. Until the first soft program verify operation and the second soft program verify operation are passed, then stops performing the soft program operation.

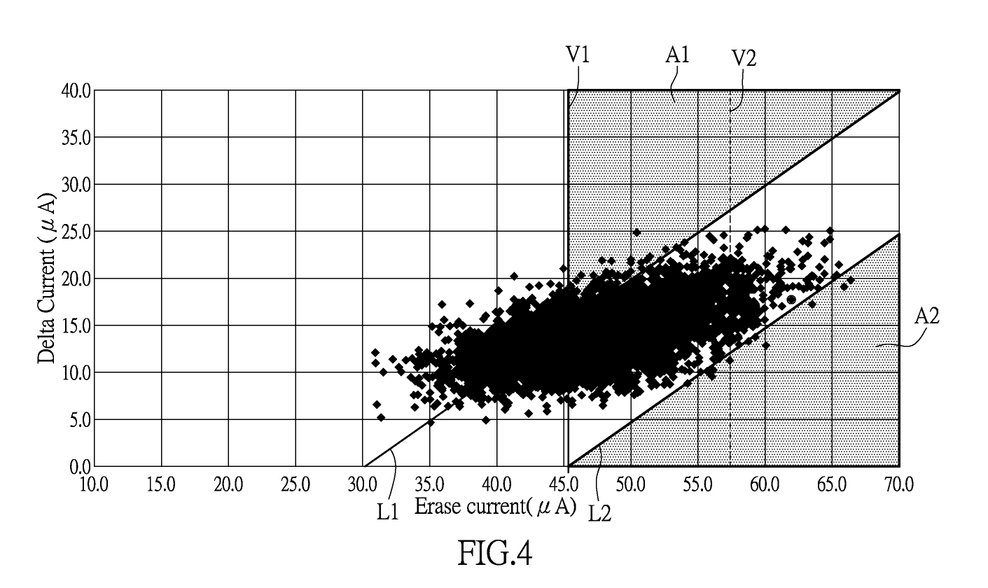

Please refer to FIG. 2 in conjunction with FIG. 4, FIG. 4 shows the soft program (SPGM) characteristics of the nonvolatile memory cells. The vertical axis indicates the cell current before soft-program minus the cell current after soft-program, indicated as the delta current, and the horizontal axis indicates the detected current in the erase operation in which each detected current is corresponding to a threshold voltage (Vt). When a memory cell is erased by a bias a corresponding erase current is obtained, and then a corresponding characteristic point is plotted in the coordinate. The region between the two lines L1 and L2 indicates the located region of characteristic points of the erased memory cells in the expected threshold voltage distribution. The line V1 indicates the current corresponding to the predetermined first verify voltage (for example, 0.7V), and the line V2 indicates the current corresponding to the predetermined second verify voltage (for example, −2V). The characteristic points located in the region left the line V1 indicates the memory cells which are not over erased. The aforementioned method shown in FIG. 2 provides two soft program verify operations respectively regarding to the first verify voltage and the second verify voltage, in which the first verify voltage (corresponding to the line V1) and the second verify voltage (corresponding to the line V2) are utilized to form the Zone 1 (enclosed by the lines V1 and V2) and the Zone 2 surrounded by the lines L1, L2 and the line V2. The memory cells with characteristic points located in Zone 1 would be soft programmed with the first soft program voltage. The memory cells with characteristic points located in Zone 2 would be soft programmed with the second soft program voltage higher than the first soft program voltage. However, the characteristic points may locate out of the region between the lines L1 and L2 due to process variation. In the prior art, a global soft program voltage is applied to the soft program operation for all memory cells, and the characteristic points located in the region A1 between the line L1 and the line V1 indicates the memory cells which are most possible be over soft programmed, in which the over soft programmed memory cell is possible to cause erroneous reading of the cell. In the same way, the characteristic points located in the region A2 between the line L2 and the line V2 indicates the memory cells which are most possible needing more than one time of soft program (if the soft program voltage is not enough) to eliminate the outcome of over erase when using the same global soft program voltage. Instead, the aforementioned method shown in FIG. 2 provides two soft program verify operations respectively regarding to the first verify voltage and the second verify voltage depending on outcome of the soft program verify operations. By setting the first soft program voltage and the second soft program voltage properly, all of the memory cells could be soft programmed appropriately.

According to above descriptions, the method of erasing a nonvolatile memory for preventing over-soft-program applies two soft program verify operations to determine the soft program voltage, that is the memory cell with higher threshold voltage is soft-programmed with a lower soft program voltage in order to preventing over-soft-program and the memory cell with lower threshold voltage is soft-programmed with a higher soft program voltage in order to saving soft-program time. And, in practically, although two soft program verify operations are carried out in the aforementioned erase algorithm, the erase time of the aforementioned erase algorithm does not remarkably longer than the erase time of the conventional erase algorithm with a global soft program voltage applied to all of the memory cells.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A method of erasing a nonvolatile memory for preventing over-soft-program, the method comprising:
performing an erase operation on at least one cell among a plurality of cells in the nonvolatile memory;
applying a first soft program verify operation to determine whether a threshold voltage of the cell is lower than a first verify voltage;
applying a second soft program verify operation to determine whether the threshold voltage of the cell is lower than a second verify voltage, wherein the second verify voltage is lower than the first verify voltage;
determining whether the threshold voltage of the cell is lower than the first verify voltage and determining whether the threshold voltage of the cell is lower than the second verify voltage;
performing a soft program operation with a first soft program voltage when the threshold voltage of the cell is lower than the first verify voltage and higher than the second verify voltage; and
performing the soft program operation with a second soft program voltage higher than the first soft program voltage when the threshold voltage of the cell is lower than both of the first verify voltage and the second verify voltage.

2. The method according to claim 1, wherein the first soft program voltage and the second soft program voltage are positive voltages applied to a word-line and a bit-line of the cell.

3. The method according to claim 1, wherein the steps of applying the first soft program verify operation and the second soft program verify operation are repeated after the soft program operation is performed, and determining whether the threshold voltage of the cell is higher than the first verify voltage or the second verify voltage again.

4. The method according to claim 3, wherein the first soft program verify operation is determined to be failed when the threshold voltage of the cell is lower than the first verify voltage, the first soft program verify operation is determined to be passed when the threshold voltage of the cell is higher than or equal to the first verify voltage.

5. The method according to claim 4, wherein the second soft program verify operation is determined to be failed when the threshold voltage of the cell is lower than the second verify voltage, the second soft program verify operation is determined to be passed when the threshold voltage of the cell is higher than or equal to the second verify voltage.

6. The method according to claim 5, wherein stops performing the soft program operation when the first soft program verify operation and the second soft program verify operation are passed.

7. The method according to claim 1, wherein the erase operation is performed by applying an erase voltage to a word-line of at least one cell of the nonvolatile memory, the erase voltage is a negative voltage.

8. The method according to claim 1, wherein a first threshold voltage distribution is obtained when the plurality of cells are stored as “1” and a second threshold voltage distribution with voltages higher than the voltages of first threshold voltage distribution is obtained when the plurality of cells are stored as “0”.

9. The method according to claim 1, wherein the erase operation performed at least some cells of the plurality of cells, and at least some of the plurality of cells are over-erased.

10. The method according to claim 5, wherein a threshold voltage distribution is obtained when the plurality of cells are stored as “1” after the erase operation is performed, then the soft program operation with the first soft program voltage is performed to change the threshold voltage of the over-erased cells to be in the region of the threshold voltage distribution when the first soft program verify operation is failed and the second program verify operation is passed.

11. The method according to claim 5, wherein a threshold voltage distribution is obtained when the plurality of cells are stored as “1” after the erase operation is performed, then the soft program operation with the second soft program voltage is performed to change the threshold voltage of the over-erased cells to be in the region of the threshold voltage distribution when the first soft program verify operation and the second program verify operation are failed.

12. The method according to claim 1, further comprising performing a pre-program operation before the step of performing the erase operation.

13. The method according to claim 1, wherein the nonvolatile memory is a flash memory.
